(19) United States
(12) Patent Application Publication
(10) Pub. No.: US 2024/0399506 A1
(43) Pub. Date: Dec. 5, 2024

(54) SUBSTRATE PROCESSING APPARATUS AND SUBSTRATE PROCESSING METHOD USING THE SAME

(71) Applicant: SAMSUNG ELECTRONICS CO., LTD., Suwon-si (KR)

(72) Inventors: Sang Min Lee, Suwon-si (KR); Seongpyo Hong, Suwon-si (KR); Sangwoo Bae, Suwon-si (KR); Namil Koo, Suwon-si (KR)

(21) Appl. No.: 18/545,864

(22) Filed: Dec. 19, 2023

(30) Foreign Application Priority Data
Jun. 2, 2023 (KR) 10-2023-0071687

(51) Int. Cl. B23K 26/38

(52) U.S. Cl. CPC B23K 26/38

(57) ABSTRACT

Embodiments of a substrate processing apparatus and substrate processing method are provided. Embodiments include a laser that directs a laser beam toward a substrate. Embodiments further include a chuck spaced apart in a first direction from the laser. Embodiments include a lower particle blocker disposed between the chuck and the laser. In some cases, the lower particle blocker includes a first particle blocker. In some cases, the first particle blocker includes a first slit that penetrates the first particle blocker in the first direction. In some cases, the first slit extends in a second direction perpendicular to the first direction.

### CROSS-REFERENCE TO RELATED APPLICATION

This U.S. nonprovisional application claims priority under 35 U.S.C. § 119 to Korean Patent Application No. 10-2023-0071687, filed on Jun. 2, 2023, in the Korean Intellectual Property Office, the disclosure of which is incorporated by reference herein in its entirety.

### TECHNICAL FIELD

Embodiments of the present inventive concepts relate to a substrate processing apparatus and a substrate processing method using the same, and more particularly, to a substrate processing apparatus capable of preventing a substrate from being attached to waste particles and a substrate processing method using the same.

### DISCUSSION OF RELATED ART

A semiconductor device can be fabricated through various processes. For example, the semiconductor device may be manufactured through a photolithography process, an etching process, a deposition process, or a test process on a substrate. In the test process, the substrate may be cut to a specific size. Various methods may be used to cut the substrate. For example, a laser may be employed to cut the substrate.

### SUMMARY

Embodiments of the present inventive concept provide a substrate processing apparatus and a substrate processing method capable of preventing waste particles from attaching to a substrate. Embodiments of the present inventive concept provide a substrate processing apparatus and a substrate processing method capable of ascertaining a time point at which a substrate is cut. Embodiments of the present inventive concept provide a substrate processing apparatus and a substrate processing method capable of reducing processing time.

Embodiments of the present inventive concepts provide a substrate processing apparatus including a laser that directs a laser beam toward a substrate. Embodiments for the present inventive concepts further include a chuck spaced apart in a first direction from the laser. Embodiments for the present inventive concepts further include a lower particle blocker disposed between the chuck and the laser. In some cases, the lower particle blocker includes a first particle blocker. In some cases, the first particle blocker includes a first slit that penetrates the first particle blocker in the first direction. In some cases, the first slit extends in a second direction perpendicular to the first direction.

Embodiments of the present inventive concepts provide a substrate processing apparatus including a chuck and a laser that directs a laser beam toward a substrate disposed on the chuck. In some embodiments, the laser includes a laser generator and a focusing lens or a mirror that reflects the laser beam generated from the laser generator toward the substrate on the chuck. In some cases, the laser includes a polarizing beam splitter disposed between the laser generator and the focusing lens or the mirror. In some cases, the laser includes an optical sensor that detects a light beam reflected from the polarizing beam splitter.

### BRIEF DESCRIPTION OF DRAWINGS

FIG. 1 is a cross-sectional view illustrating a substrate processing apparatus according to some embodiments of the present inventive concepts.

FIG. 2 is a cross-sectional view illustrating a lower particle blocker according to some embodiments of the present inventive concepts.

FIG. 3 is a cross-sectional view illustrating a first particle blocker according to some embodiments of the present inventive concepts.

FIG. 4 is a perspective view illustrating a first particle blocker according to some embodiments of the present inventive concepts.

FIG. 5 is a plan view illustrating a first particle blocker according to some embodiments of the present inventive concepts.

FIG. 6 is a cross-sectional view illustrating an upper particle blocker according to some embodiments of the present inventive concepts.

FIG. 7 is a simplified schematic diagram illustrating a laser according to some embodiments of the present inventive concepts.

FIG. 8 is a flow chart illustrating a substrate processing method according to some embodiments of the present inventive concepts.

FIGS. 9, 10, 11, 12, 13, 14, 15, 16, 17, 18, and 19 are diagrams illustrating a substrate processing method based on the flow chart of FIG. 8.

### DETAILED DESCRIPTION

Hereinafter, the inventive concepts are described in more detail. Embodiments according to the present inventive concept are described in more detail with reference to the accompanying drawings Like reference numerals may indicate like components throughout the description. Omitted details are understood to be the same as described for corresponding elements elsewhere in the disclosure.

Referring to the detailed description, D1 may indicate a first direction, D2 may indicate a second direction that intersects the first direction D1, and D3 may indicate a third direction that intersects each of the first direction D1 and the second direction D2. The first direction D1 may be called a vertical direction or an upward direction. In addition, the second direction D2 or third direction D3 may be called a horizontal direction.

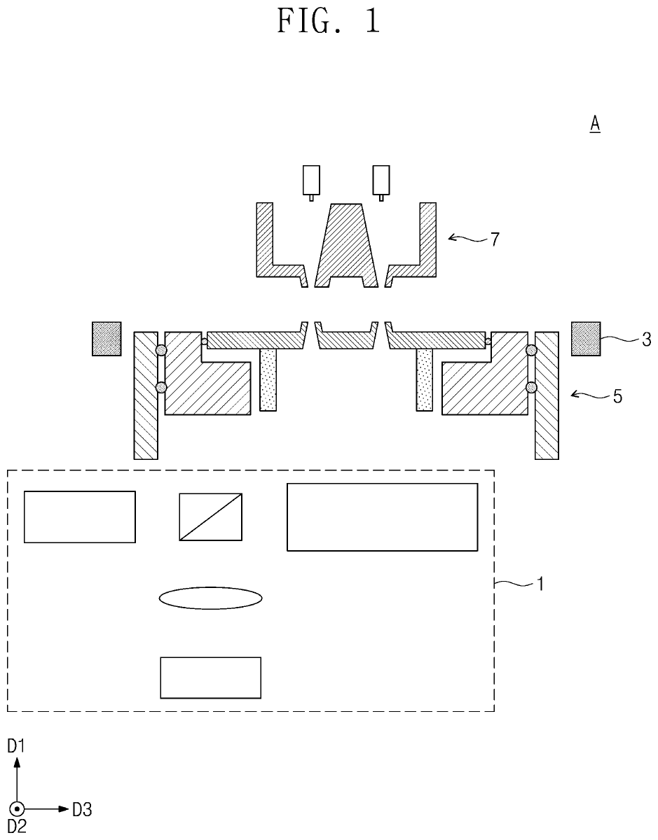

FIG. 1 is a cross-sectional view illustrating a substrate processing apparatus according to some embodiments of the present inventive concepts. Referring to FIG. 1, a substrate processing apparatus A is provided. The substrate processing apparatus A may be configured to perform a process on a substrate. For example, the substrate processing apparatus A may cut a substrate. The substrate A may perform an ablation dicing process in which a laser is used to cut a substrate. The term “substrate” used in this disclosure may denote a silicon (Si) wafer, but the present inventive concepts are not necessarily limited thereto. The substrate processing apparatus A may cut a substrate for various purposes. For example, the substrate processing apparatus A may cut a portion of a substrate to test the portion of the substrate. According to some embodiments, the substrate processing apparatus A may include a laser 1, a chuck 3, a lower particle blocker 5, and an upper particle blocker 7.

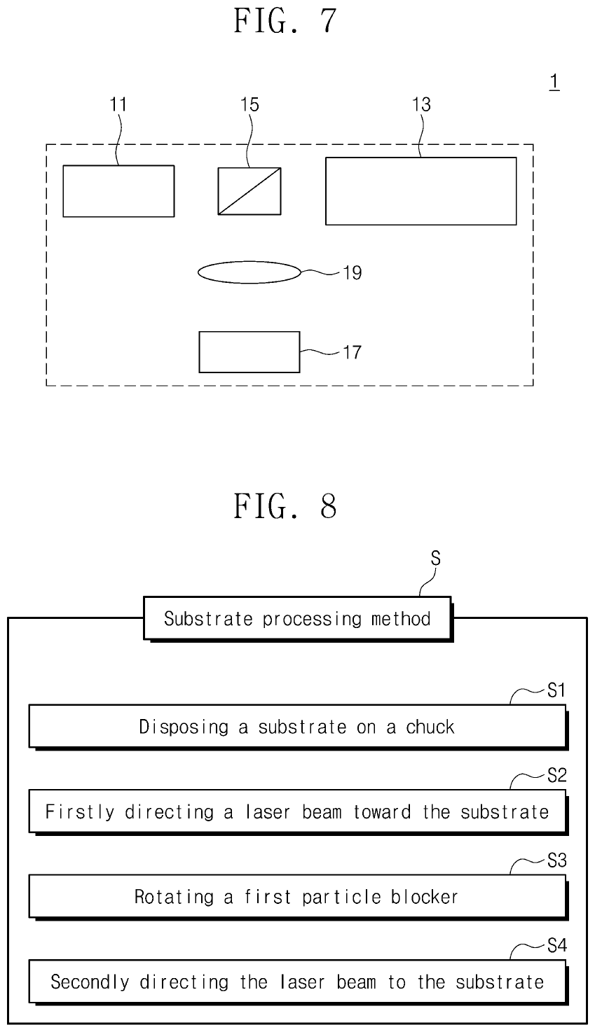

The laser 1 may direct a laser. In some cases, the laser 1 may direct a laser beam. For example, the laser 1 may direct a laser beam to a substrate disposed on the chuck 3. In some cases, the laser 1 may detect a laser beam. For example, the laser 1 may detect a laser beam reflected from the substrate. The laser 1 may be disposed under the chuck 3. Accordingly, the laser 1 may direct a laser beam toward the substrate from a level below the substrate. Further details on the laser 1 are described with reference to FIG. 7.

The chuck 3 may support (or secure) the substrate. The chuck 3 may be disposed above the laser 1. For example, the chuck 3 may be spaced apart from the laser 1 in the first direction D1. The chuck 3 may support the substrate in various manners. For example, the chuck 3 may use a clamping mechanism to support the substrate. For example, the chuck 3 may use vacuum pressure to support the substrate. In some embodiments, the chuck 3 may be an electrostatic chuck (ESC) configured to support the substrate using electrostatic force with static electricity. When the substrate is disposed on the chuck 3, at least a portion of the substrate may be exposed to the laser 1.

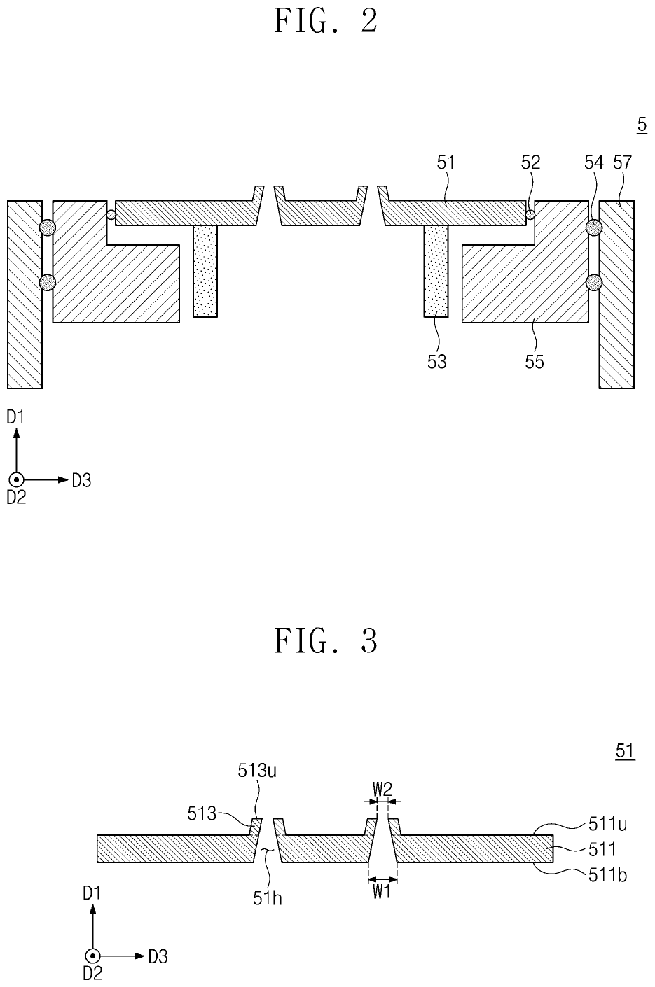

In an embodiment, the lower particle blocker 5 may be disposed between the chuck 3 and the laser 1 in the first direction D 1. For example, at least a portion of the lower particle blocker 5 may be disposed between the chuck 3 and the laser 1. The lower particle blocker 5 may prevent waste particles from attaching to a bottom surface of the substrate caused by cutting the substrate disposed on the chuck 3. Details on the lower particle blocker 5 are described with reference to FIGS. 2-5.

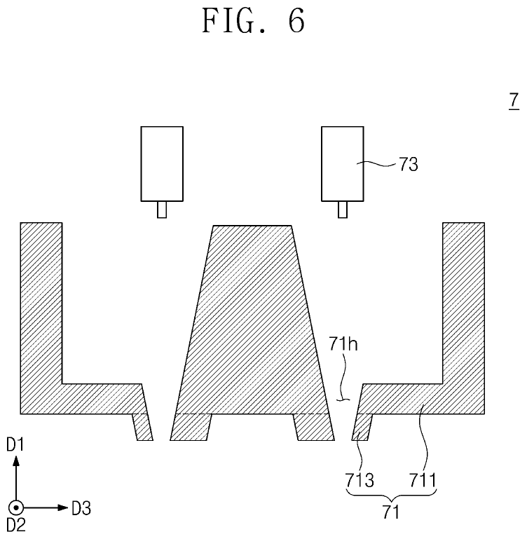

In an embodiment, the upper particle blocker 7 may be disposed on the chuck 3. The upper particle blocker 7 may prevent waste particles from attaching to a top surface of the substrate caused by cutting the substrate disposed on the chuck 3. Details on the upper particle blocker 7 are described with reference to FIG. 6.

FIG. 2 is a cross-sectional view illustrating a lower particle blocker according to some embodiments of the present inventive concepts. Referring to FIG. 2, the lower particle blocker 5 may include a first particle blocker 51, a support member 53, a rotational driver 55, and an elevation driver 57. The lower particle blocker 5 may further include a first guide member 52 and a second guide member 54.

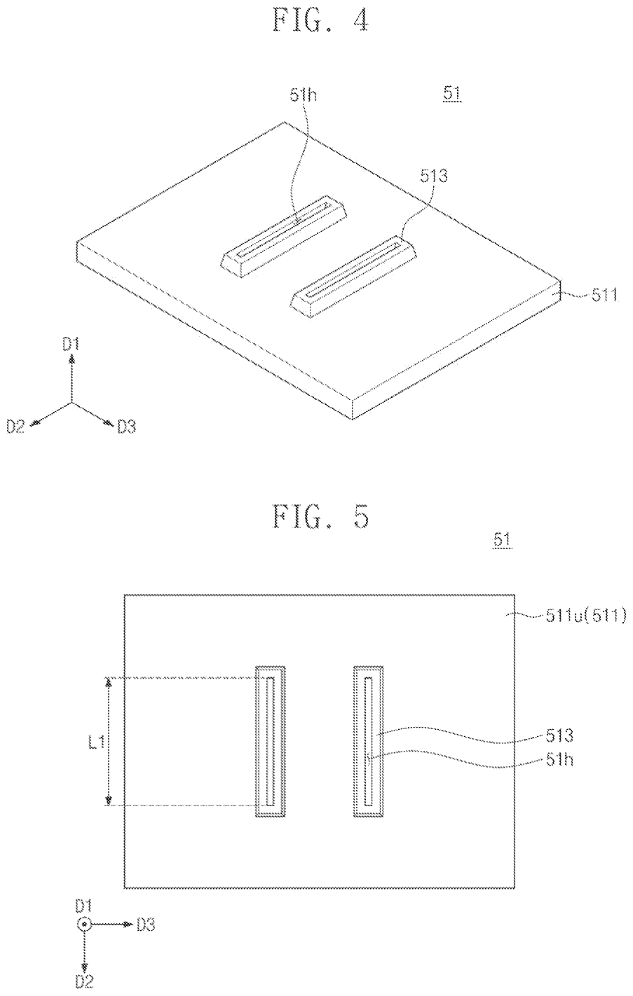

The first particle blocker 51 may contact a substrate disposed on the chuck (e.g., the chuck 3 described with reference to FIG. 1). In some cases, a level of the uppermost surface of the first particle blocker 51 of the lower particle blocker 5 is in a same level as a level of the upper surface of the chuck 3. For example, a bottom surface of the substrate may contact the uppermost surface of the first particle blocker 51 and the upper surface of the chuck 3. The first particle blocker 51 may block waste particles generated from the substrate from being attached to the bottom surface of the substrate. The first particle blocker 51 may include one or more metal, polymer-based materials, or a combination thereof. Details on the first particle blocker 51 are described with reference to FIG. 3.

The support member 53 may support the first particle blocker 51. The support member 53 may be disposed under the first particle blocker 51 and may be in contact with a bottom surface of the first particle blocker 51. in blocker

The rotational driver 55 may rotate the first particle blocker 51. For example, the rotational driver 55 may rotate the first particle blocker 51 about an axis that extends in the first direction D1. In some cases, the rotational driver 55 may include an actuator, for example, an electrical actuator, a pneumatic actuator, or a hydraulic actuator. A first guide member 52 may be disposed between the rotational driver 55 and the first particle blocker 51 along the third direction D3.

The first guide member 52 may be disposed between an inner side surface of the rotational driver 55 and an outer side surface of the first particle blocker 51. In one embodiment, the first guide member 52 may be disposed between a bottom surface of the first particle blocker 51 and a top surface of the rotational driver 55. For example, the first guide member 52 may be disposed between the rotational driver 55 and the first particle blocker 51 along the first direction D1. In one aspect, the first guide member 52 may include a bearing or the like, but the present inventive concepts are not necessarily limited thereto.

The rotational driver 55 may be disposed outside the first particle blocker 51. For example, the rotational driver 55 may partially surround a side surface and a bottom surface of the first particle blocker 51. For example, the rotational driver 55 may be positioned outside a first slit (e.g., the first slit 51h described with reference to FIG. 3) of the first particle blocker 51. As used herein, the term “outside” refers to a direction departing from a central axis of a component, for example, the first particle blocker 51.

The elevation driver 57 may move the first particle blocker 51 along the first direction D1. In some cases, the elevation driver 57 may move the first particle blocker 51 and rotational driver 55 along the first direction D1. The elevation driver 57 may include an actuator, for example, an electrical actuator, a pneumatic actuator, or a hydraulic actuator. A second guide member 54 may be disposed between the elevation driver 57 and the first particle blocker 51. In some cases, the second guide member 54 may be disposed between the elevation driver 57 and the rotational driver 55. In one aspect, the second guide member 54 may include a bearing or the like, but the present inventive concepts are not necessarily limited thereto.

FIG. 3 is a cross-sectional view illustrating a first particle blocker according to some embodiments of the present inventive concepts. FIG. 4 is a perspective view illustrating a first particle blocker according to some embodiments of the present inventive concepts. FIG. 5 is a plan view illustrating a first particle blocker according to some embodiments of the present inventive concepts.

Referring to FIGS. 3 to 5, the first particle blocker 51 may include a first slit 51h. The first slit 51h may extend vertically along the first direction. For example, the first slit 51h may penetrate the first particle blocker 51 in the first direction D1. The first slit 51h may extend in a horizontal direction. For example, the first slit 51h may extend in the second direction D2. A first length L1 may indicate a length of the first slit 51h in the second direction D2. For example, the first length L1 may range from about 0.5 cm to about 1.5 cm. For example, the first length L1 may be about 1.0 cm. The present inventive concepts, however, are not necessarily limited thereto. For example, the first particle blocker 51 may include one or more first slits 51h. For example, as shown in FIG. 5, two first slits 51h may be provided. The two first slits 51h may be spaced apart from each other in the third direction D3.

In some embodiments, the first particle blocker 51 may include a first plate 511 and a protrusion 513. The first plate 511 may have a plate shape that extends in directions perpendicular to the first direction D1. As used herein, the term “plate shape” refers to a 3D shape having rectangular side surfaces. For example, the side views of the first plate 511 may be a rectangle. The top view of the first plate 511 may be a rectangle, square, or circle. The first slit 51h may penetrate the first plate 511 in the first direction D1. The first plate 511 may have a tetragonal shape in a plan view, but the present inventive concepts are not necessarily limited thereto. The first plate 511 may include a stiff material. For example, the first plate 511 may include metal. The present inventive concepts, however, are not necessarily limited thereto, and the first plate 511 may include other suitable materials.

The protrusion 513 may protrude from a top surface 511u of the first plate 511 in the first direction D1. The protrusion 513 may extend in the second direction D2. The protrusion 513 may include a different material from the material of the first plate 511. The protrusion 513 may include a soft material. Therefore, when a substrate is in contact with the protrusion 513, the substrate is not damaged. In some cases, the protrusion 513 may include a polymer-based material. For example, the protrusion 513 may include rubber. In some cases, for example, the protrusion 513 may include a combination of rubber and metal. For example, a top surface 513u of the protrusion 513 may include rubber, and a remaining portion of the protrusion 513 may include metal. For example, an upper portion of the protrusion 513 may include rubber, and a lower portion of the protrusion 513 may include metal. The present inventive concepts, however, are not necessarily limited thereto, and the protrusion 513 may include other materials capable of preventing a substrate from damaging.

The first slit 51h may penetrate the protrusion 513 in the first direction D1. For example, the first slit 51h may connect a bottom surface 511b of the first plate 511 to a top surface 513u of the protrusion 513. Therefore, an upper end of the first slit 51h may be located at a level higher than a level of the top surface 511u of the first plate 511. When one or more first slits 51h are provided, protrusions 513 may also be provided, respectively. For example, when two first slits 51h are provided, two protrusions 513 may be provided. The two protrusions 513 may be spaced apart in the third direction D3 from each other. In some cases, protrusion 513 includes a left portion and a right portion. The first slit 51h is disposed between the left portion and the right portion of the protrusion 513 along the third direction D3.

The first slit 51h may have an irregular width measured in the third direction D3. For example, a first width W1 may indicate a width at a lower end of the first slit 51h. In some cases, the lower end of the first slit 51h is in a same level as the bottom surface 551b of the first plate 551. A second width W2 may indicate a width at an upper end of the first slit 51h. In some cases, the upper end of the first slit 51h is in a same level as the top surface 513u of the protrusion 513. The second width W2 may be less than the first width W1. For example, a width of the first slit 51h measured in the third direction D3 may decrease along the first direction D1. As shown in FIG. 3, for example, the first slit 51h has a shape of an isosceles trapezoid in the cross-sectional view. For example, the shape of the first slit 51h decreases the amount of waste particles from attaching to the substrate. The present inventive concepts, however, are not necessarily limited thereto.

FIG. 6 is a cross-sectional view illustrating an upper particle blocker according to some embodiments of the present inventive concepts. Referring to FIG. 6, the upper particle blocker 7 may include a second particle blocker 71 and a fluid sprayer 73.

In one embodiment, the second particle blocker 71 may include a second slit 71h. The second slit 71h may penetrate the second particle blocker 71 in the first direction D1. In some cases, the second slit 71h may have a tetragonal shape when viewed in plan, but the present inventive concepts are not necessarily limited thereto. The second particle blocker 71 may include an upper blocking body 711 and an extension 713. The upper blocking body 711 may have a cylindrical shape. The extension 713 may downwardly extend from the upper blocking body 711. While performing a substrate process, a bottom surface of the extension 713 may be in contact with an upper surface of a substrate on the chuck (e.g., chuck 3 described with reference to FIG. 1). The second slit 71h may connect an upper surface of the upper blocking body 711 to the bottom surface of the extension 713.

The fluid sprayer 73 may downwardly spray a fluid. The fluid sprayer 73 may spray a fluid toward the second slit 71h. For example, while performing a substrate process, the fluid sprayer 73 may spray air toward the second slit 71h. The fluid sprayer 73 may include a compressor, a nozzle, and other suitable spray mechanisms. A fluid sprayed from the fluid sprayer 73 may prevent waste particles, generated from cutting the substrate, from attaching to the substrate. In some cases, the fluid sprayer 73 is disposed on the chuck 3, but the present inventive concepts are not necessarily limited thereto. For example, the fluid sprayer 73 may be disposed below the chuck 3. Accordingly, the fluid sprayer 73 may spray a fluid toward a bottom surface of the substrate.

FIG. 7 is a simplified schematic diagram illustrating a laser according to some embodiments of the present inventive concepts. Referring to FIG. 7, the laser 1 may include a laser generator 11, a focusing lens or a mirror 13, a polarizing beam splitter (PBS) 15, an optical sensor 17, and a lens 19.

According to an aspect of the present inventive concepts, the laser generator 11 may produce a laser beam. The laser beam generated from the laser generator 11 may be directed toward the focusing lens or the mirror 13. In some cases, an optical element includes a focusing lens or a focusing mirror.

The focusing lens or the mirror 13 may reflect the laser beam toward the chuck (e.g., chuck 3 described with reference to FIG. 1). For example, the focusing lens or the mirror 13 may reflect the laser beam generated from the laser generator 11 toward the substrate disposed on the chuck 3. In some cases, the focusing lens or the mirror 13 may reflect the laser beam reflected from the substrate toward the polarizing beam splitter 15. For example, the focusing lens or the mirror 13 may include a minor, but the present inventive concepts are not necessarily limited thereto. The focusing lens or the mirror 13 may focus the laser beam on the substrate. In addition, the focusing lens or the mirror 13 may scan the laser beam. For example, the focusing lens or the mirror 13 may move an focusing point of the laser beam such that the laser beam is focused on a plurality of points of the substrate on the chuck 3. In some cases, the focusing point refers to a point on the substrate where the laser beam is directed to. In some cases, the focusing lens or the mirror 13 may be rotatable. Accordingly, the laser beam reflected from the focusing lens or the mirror 13 may be directed to various points on the substrate.

The polarizing beam splitter 15 may be disposed between the laser generator 11 and the focusing lens or the minor 13. The polarizing beam splitter 15 may pass the laser beam directed from the laser generator 11. For example, the laser beam produced from the laser generator 11 may pass through the polarizing beam splitter 15 and may be directed to the focusing lens or the mirror 13. The polarizing beam splitter 15 may reflect the laser beam reflected from the focusing lens or the mirror 13. The reflected laser beam from the substrate and the focusing lens or the minor 13 may be reflected from the polarizing beam splitter 15 and directed to the optical sensor 17.

The optical sensor 17 may detect a light beam (or laser beam) reflected from the polarizing beam splitter 15. The optical sensor 17 may include a PD sensor, but the present inventive concepts are not necessarily limited thereto. The lens 19 may be positioned between the polarizing beam splitter 15 and the optical sensor 17. The laser beam reflected from the polarizing beam splitter 15 may pass through the lens 19, and may be detected by the optical sensor 17.

FIG. 8 is a flow chart illustrating a substrate processing method according to some embodiments of the present inventive concepts. Referring to FIG. 8, a substrate processing method S may be provided. The substrate processing method S may be a method of processing a substrate using the substrate processing apparatus (e.g., the substrate processing apparatus A described with reference to FIGS. 1-7). The substrate processing method S may include disposing a substrate on a chuck (S1), firstly directing a laser beam toward the substrate (S2), rotating a first particle blocker (S3), and secondly directing the laser beam to the substrate (S4).

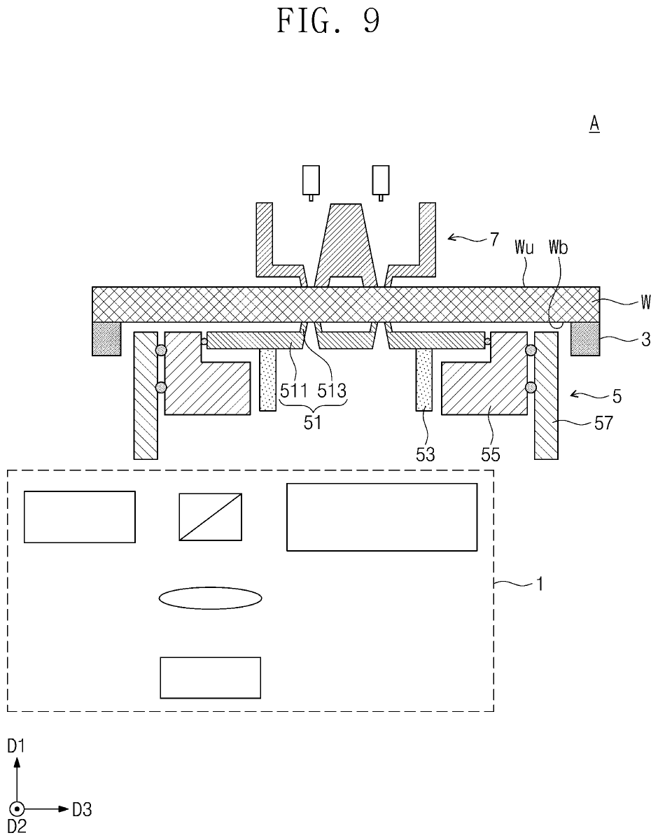

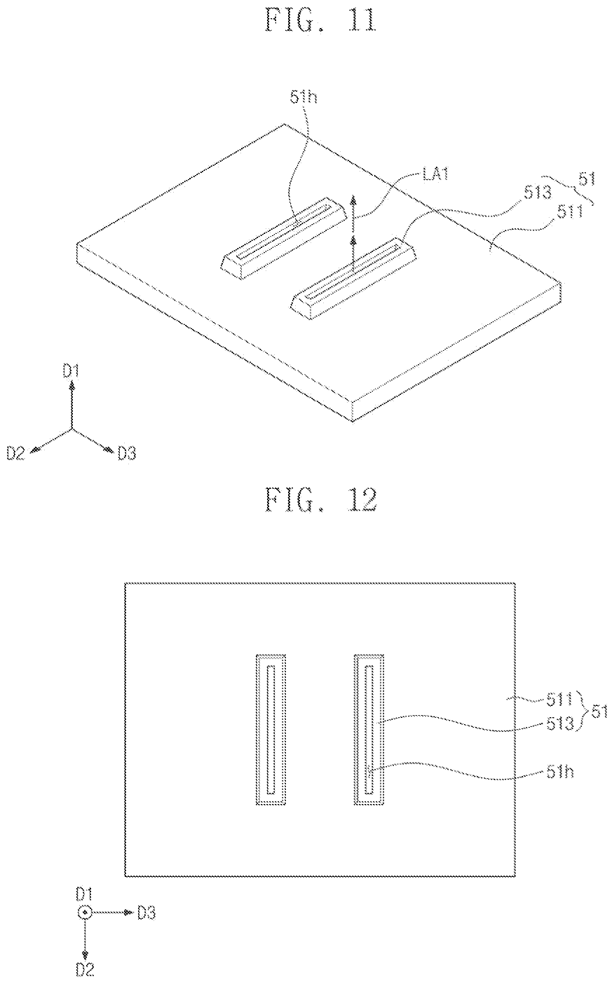

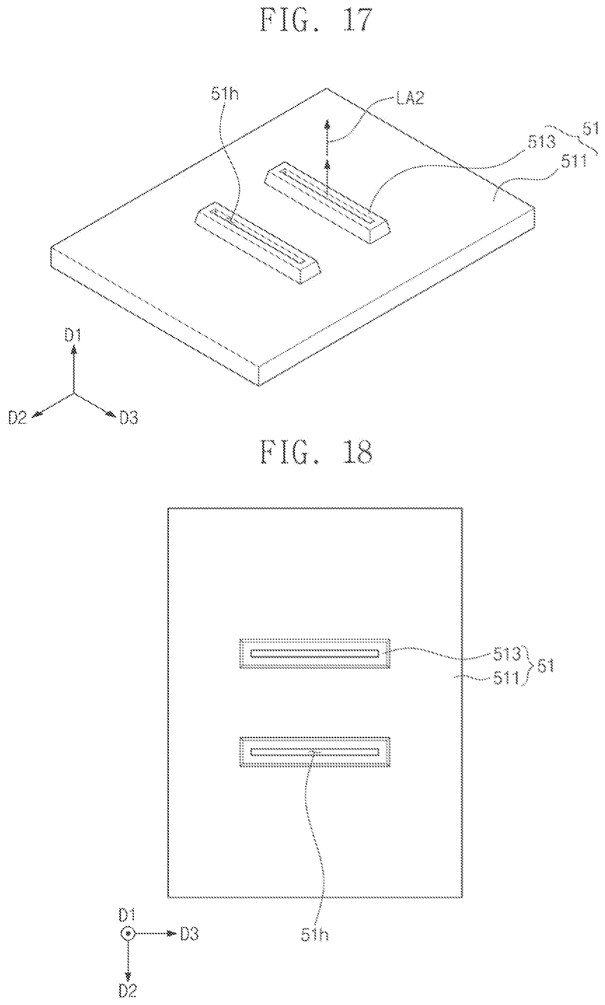

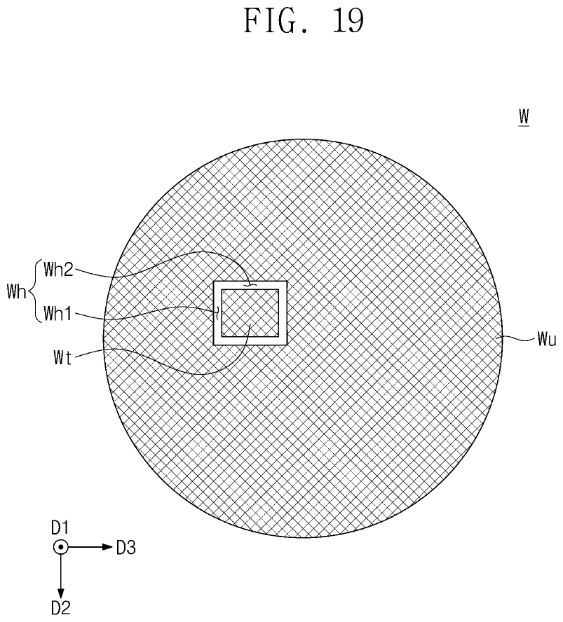

Further details regarding substrate processing method S of FIG. 8 are described with reference to FIGS. 9-19. FIGS. 9-19 are diagrams illustrating a substrate processing method based on the flow chart of FIG. 8.

Referring to FIGS. 8 and 9, the step of disposing a substrate on a chuck 51 may include disposing a substrate W on the chuck 3. In some cases, when the chuck 3 includes a clamping mechanism, the chuck 3 may secure the substrate W by clamping an edge region of the substrate W. In a state where the substrate W is disposed on the chuck 3, a first surface of the substrate W may be a bottom surface Wb. A second surface of the substrate W may be a top surface Wu. In some cases, the top surface Wu may be an active surface of the substrate W, but the present inventive concepts are not necessarily limited thereto. Before a process is performed, the lower particle blocker 5 may contact the substrate W. For example, the first particle blocker 51 may contact the bottom surface Wb of the substrate W.

In some embodiments, the first particle blocker 51 may move upwardly so that the top surface (e.g., top surface 513u described with reference to FIG. 3) of the protrusion (e.g., protrusion 513 described with reference to FIG. 3) may contact the bottom surface Wb of the substrate W. In addition, the upper particle blocker 7 may contact the substrate W. For example, the upper particle blocker 7 may move downwardly so that the bottom surface of the extension (e.g., extension 713 described with reference to FIG. 6) may contact the upper surface Wu of the substrate W. Accordingly, the substrate W may be clamped by the first particle blocker 51 and the upper particle blocker 7.

Referring to FIGS. 8, and 10-12, the step of firstly directing a laser toward the substrate S2 may include directing a laser beam LA1 generated from the laser 1 to the bottom surface Wb of the substrate W. The laser beam LA1 generated from the laser generator 11 may pass through the polarizing beam splitter 15 to be deflected from the focusing lens or the mirror 13. The laser beam LA1 deflected from the focusing lens or the mirror 13 may pass through the first slit 51h of the first particle blocker 51. For example, the first slit 51h of the first particle blocker 51 extends along the second direction D2. The laser beam LA1 that has passed through the first slit 51h may be directed to the bottom surface Wb of the substrate W. The focusing lens or the minor 13 may cause the laser beam LA1 to be focused on a specific point on the bottom surface Wb of the substrate W. The laser beam LA1 may cut the substrate W based on the focused laser beam LA1.

In some embodiments, the focusing lens or the minor 13 may scan a laser beam. The focusing lens or the mirror 13 may rotate such that a point on which the laser beam LA1 is focused may move on the bottom surface Wb of the substrate W. For example, the scanning of the focusing lens or the minor 13 may linearly move the focused point of the laser beam LA1 on the bottom surface Wb of the substrate W. For example, the focused point of the laser beam LA1 may move along the second direction. Accordingly, the substrate W may be linearly cut. While the laser beam LA1 cuts the substrate W, waste particles may be created from the substrate W. The particle may fall down due to gravity. For example, the waste particles may fall down through the first slit 51h of the first particle blocker 51. The waste particles may be blocked by the protrusion 513 from attaching to the bottom surface Wb of the substrate W. Accordingly, the waste particles are not diffused laterally on the bottom surface Wb of the substrate W.

Referring to FIGS. 8 and 13, in the step of firstly directing a laser beam toward the substrate S2, a portion of the laser beam LA1 may be reflected from the bottom surface Wb of the substrate W. The laser beam LA1 reflected from the bottom surface Wb of the substrate W may be a reflection laser beam LAr. The focusing lens or the mirror 13 may deflect the reflection laser beam LAr to the polarizing beam splitter 15. The polarizing beam splitter 15 may deflect the reflection laser beam LAr to the optical sensor 17. The reflection laser beam LAr deflected from the polarizing beam splitter 15 may pass through the lens 19 and may be received by the optical sensor 17. The optical sensor 17 may detect the reflection laser beam LAr.

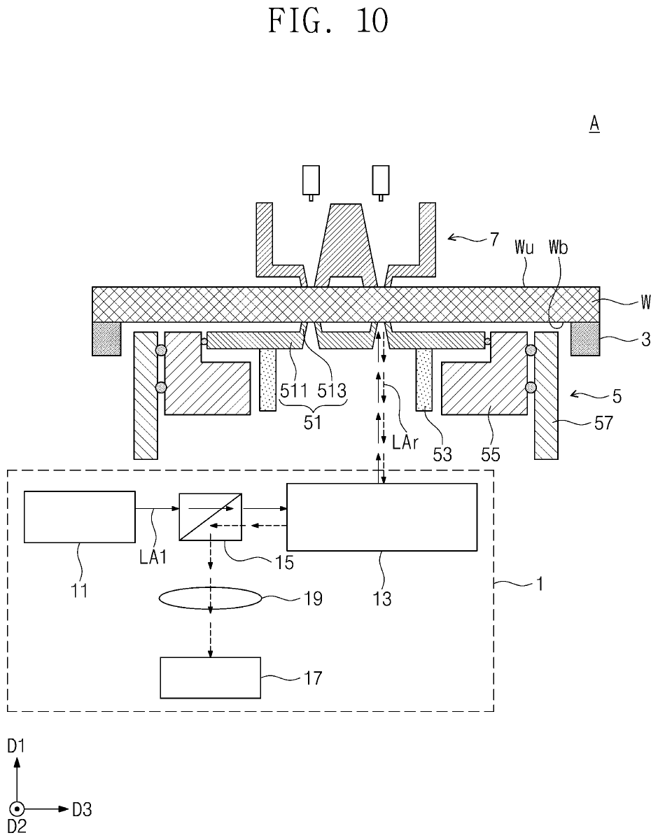

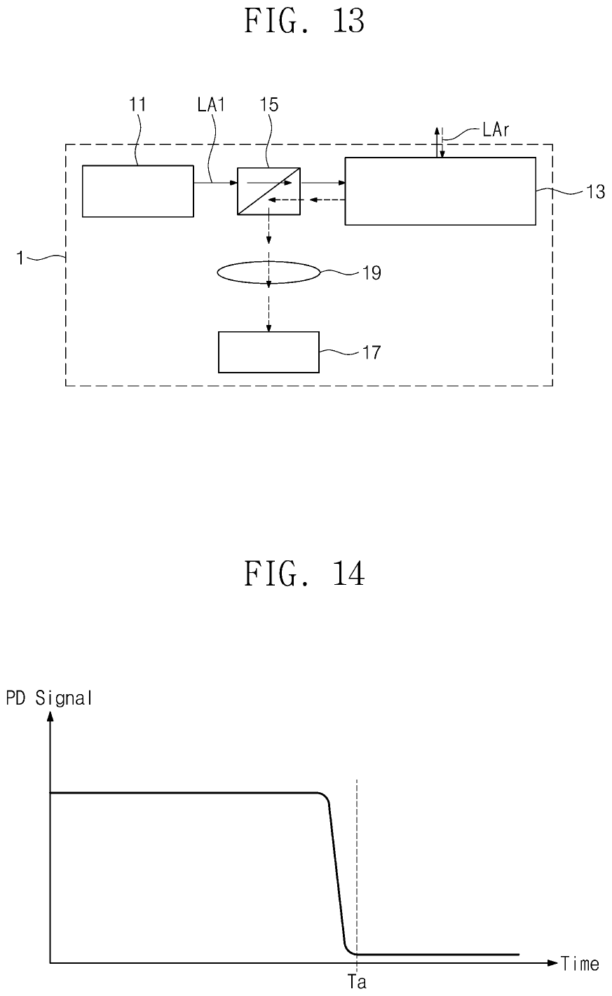

Referring to FIG. 14, a timing diagram is provided. For example, a horizontal axis may indicate time and the vertical axis may indicate the intensity of light detected by the optical sensor (e.g., the optical sensor 17 described with reference to FIG. 13). Before the substrate (e.g., substrate W described with reference to FIG. 10) is completely cut, the reflection laser beam LAr may be deflected toward the optical sensor 17 from the bottom surface (e.g., bottom surface Wb described with reference to FIG. 10) of the substrate W. Thus, before the substrate W is completely cut, the optical sensor 17 may detect intensity of light that is greater than a reference value.

When the substrate W is completely cut, there may be an abrupt reduction in the intensity of the reflection laser beam LAr reflected from the substrate W. Therefore, the intensity of light detected by the optical sensor 17 may be reduced. For example, a signal of the reflection laser beam LAr might not be received by the optical sensor 17. A time point Ta may represent a time point at which the substrate W is completely cut because of the reduction of the intensity of light detected by the optical sensor 17. In some cases, for example, time point Ta may represent a time at which the optical sensor 17 might not receive a signal. Thus, the laser beam may be terminated at the time point TA, when no signal of the reflection laser beam LAr is received by the optical sensor 17. In some cases, the fluid sprayer (e.g., fluid sprayer 73 described with reference to FIG. 6) may spray a fluid to the substrate W disposed on the chuck (e.g., chuck 3 described with reference to FIG. 10). Accordingly, waste particles may be prevented from attaching to the top surface Wu of the substrate W. In some embodiments, when the fluid sprayer 73 is disposed under the chuck 3, the fluid sprayer 73 may spray a fluid to the bottom surface Wb of the substrate W. Accordingly, waste particles may be prevented from attaching to the bottom surface Wb of the substrate W.

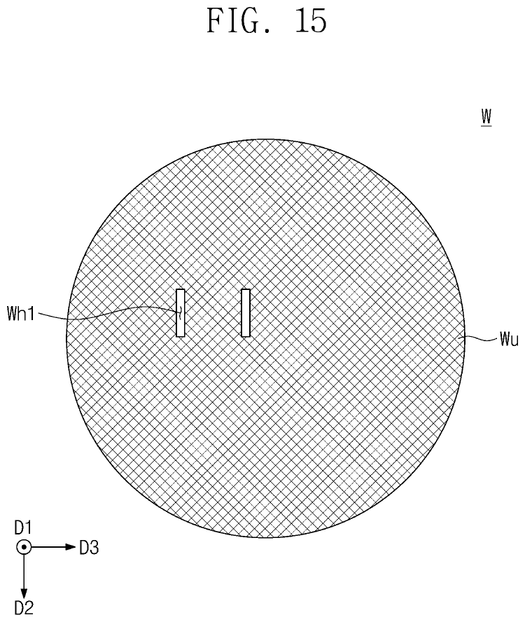

Referring to FIG. 15, a first cutting hole Wh1 may be formed in the substrate W. When two slits (e.g., the first slit 51h described with reference to FIG. 11) are provided, two first cutting holes Wh1 may be formed.

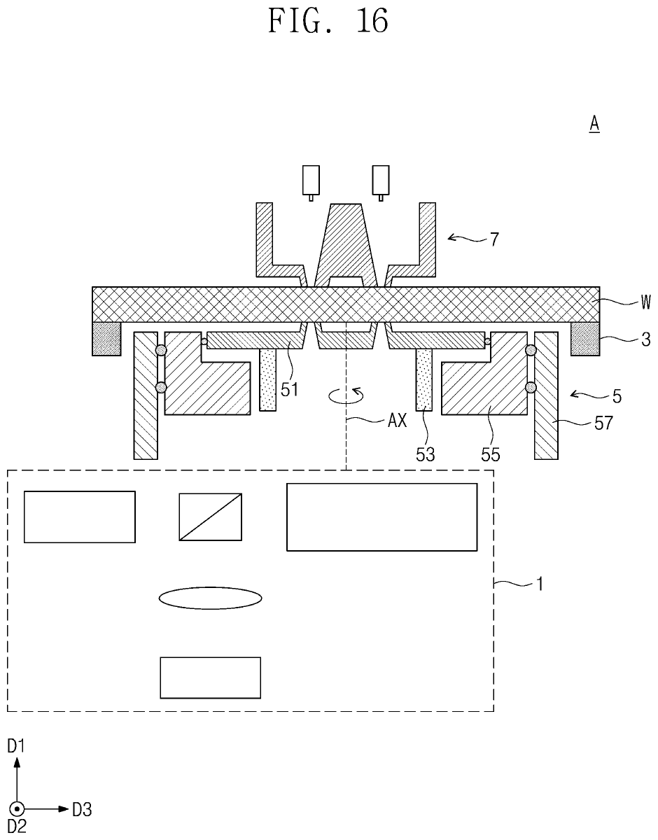

Referring to FIGS. 8 and 16, the step of rotating a first particle blocker S3 may include the first particle blocker 51 rotating about an axis AX that extends in the first direction D1. For example, the first particle blocker 51 may rotate about 90°. The first particle blocker 51 may be rotated using the rotational driver 55. In some embodiments, before the first particle blocker 51 rotates, the first particle blocker 51 may descend. For example, the first particle blocker 51 might not contact the bottom surface Wb of the substrate W.

After the first particle blocker 51 moves away (or descends) from the substrate W, the first particle blocker 51 may rotate. For example, the first particle blocker 51 may rotate in the descended state. As the first particle blocker 51 rotates in the descended state, the substrate W may be stationary at a position without rotation during the rotation of the first particle blocker 51. After the rotation of the first particle blocker 51, the first particle blocker 51 may move toward (or ascend) the first particle blocker 51. Thus, the rotated first particle blocker 51 may contact the substrate W. For example, the protrusion 513 of the rotated first particle blocker 51 may contact the bottom surface Wb of the substrate W. Accordingly, the substrate W may be clamped by the rotated first particle blocker 51 and the upper particle blocker 7.

Referring to FIGS. 8, and 17-18, the step of secondly directing the laser beam toward the substrate S4 may include allowing a laser beam LA2 to pass through the first slit 51h. For example, the first slit 51h may extend within the first particle blocker 51 along the third direction D3. The laser beam LA2 that has passed through the first slit 51h may reach the bottom surface Wb of the substrate (e.g., substrate W described with reference to FIG. 10). The laser beam LA2 may cut the substrate W.

Referring to FIG. 19, a second cutting hole Wh2 may be formed on the substrate W. When two slits (e.g., slits 51h described with reference to FIG. 11) are provided, two second cutting holes Wh2 may be formed. The second cutting hole Wh2 and the first cutting hole Wh1 may be connected to each other. accordingly, one cutting hole Wh may be formed. For example, the cutting hole Wh includes the first cutting hole Wh1 and the second cutting hole Wh2. The cutting hole WH may have a tetragonal frame shape in the plan view. Accordingly, a portion Wt may be separated from the substrate W.

According to a substrate processing apparatus and a substrate processing method of the present inventive concepts, a lower particle blocking apparatus may be used to prevent a substrate from contamination caused by waste particles generated from the substrate. For example, the waste particles generated from the substrate may fall down through a first slit, and a protrusion may prevent the waste particles from diffusing laterally on the bottom surface of the substrate. Therefore, the waste particles may be prevented from attaching to a portion cut from the substrate. Accordingly, the substrate may be free of contamination. In some cases, the portion cut from the substrate may also be free of contamination. Accordingly, an accurate test on a portion of the substrate may be performed.

According to a substrate processing apparatus and a substrate processing method of the present inventive concepts, a first particle blockermember having two slits may be used while rotating the first particle blocker. Accordingly, a support member for supporting the first particle blocker may be spaced from the two slits. For example, a path of laser beam directed from a laser might not be obstructed. In some cases, even when an ordinary laser is used, a rotational first particle blocker may be used to prevent a substrate from contaminated from waste particles.

According to a substrate processing apparatus and a substrate processing method of the present inventive concepts, a time point at which a substrate is cut may be accurately ascertained. For example, an optical sensor may be used to detect a reflection laser beam reflected from the substrate to determine whether the substrate is completely cut. Laser beam may be terminated at a time point when the substrate is completely cut. Accordingly, even after the substrate is completely cut, waste particles generated from cutting the substrate may be prevented from attaching to a top surface of the substrate. Accordingly, an active surface of the substrate may be protected.

According to a substrate processing apparatus and a substrate processing method of the present inventive concepts, a time point of substrate cutting may be determined to reduce a processing time. For example, laser beam may be terminated at a time point when a substrate is completely cut, and additional laser beam generation may be avoided. Accordingly, processing time for laser beam generation may be reduced. In some cases, power consumption and manufacturing costs may be reduced.

According to a substrate processing apparatus and a substrate processing method of the present invention, a substrate may be prevented from being contaminated with waste particles generated by cutting the substrate. According to a substrate processing apparatus and a substrate processing method of the present invention, a time point at which the substrate is cut may be ascertained. According to a substrate processing apparatus and a substrate processing method of the present invention, processing time may be reduced.

Effects of the present inventive concepts are not necessarily limited to the mentioned above, other effects which have not been mentioned above will be clearly understood to those skilled in the art from the following description. Although the present inventive concepts have been described in connection with some embodiments of the present inventive concepts illustrated in the accompanying drawings, it will be understood to those skilled in the art that various changes and modifications may be made without departing from the technical spirit and essential feature of the present inventive concepts. Therefore, it is understood that the disclosed embodiments described should be considered illustrative and not limitative in all aspects.

In this disclosure and the following claims, the word “or” indicates an inclusive list such that, for example, the list of X, Y, or Z means X or Y or Z or XY or XZ or YZ or XYZ. Also the phrase “based on” is not used to represent a closed set of conditions. For example, a step that is described as “based on condition A” can be based on both condition A and condition B. In other words, the phrase “based on” shall be construed to mean “based at least in part on.” Also, the words “a” or “an” indicate “at least one.”

What is claimed is:

1. A substrate processing apparatus, comprising:
a laser that directs a laser beam toward a substrate;
a chuck spaced apart from the laser in a first direction; and
a lower particle blocker disposed between the chuck and the laser,
wherein the lower particle blocker includes a first particle blocker,
wherein the first particle blocker includes a first slit that penetrates the first particle blocker in the first direction, and
wherein the first slit extends along a second direction perpendicular to the first direction.

2. The substrate processing apparatus of claim 1, wherein:
the lower particle blocker includes two first slits, and
wherein the two first slits are spaced apart from each other in a third direction perpendicular to the first direction and the second direction.

3. The substrate processing apparatus of claim 1, wherein the lower particle blocker further includes a rotational driver that rotates the first particle blocker about an axis that extends in the first direction.

4. The substrate processing apparatus of claim 3, wherein the rotational driver is spaced apart from the first particle blocker.

5. The substrate processing apparatus of claim 1, wherein the first particle blocker further comprises:
a first plate; and
a protrusion that protrudes from a top surface of the first plate in the first direction,
wherein the protrusion includes a material different from a material of the first plate, and
wherein the first slit penetrates the first particle blocker in the first direction and connects a bottom surface of the first plate to a top surface of the protrusion.

6. The substrate processing apparatus of claim 1, wherein:
a width of the first slit measured in a third direction decreases along the first direction, the third direction is perpendicular to the first direction and the second direction, and
wherein a cross-section of the first slit has a shape of an isosceles trapezoid.

7. The substrate processing apparatus of claim 1, further comprising an upper particle blocker disposed on the chuck,
wherein the upper particle blocker includes:
a fluid sprayer; and
a second particle blocker disposed under the fluid sprayer,
wherein the second particle blocker includes a second slit that penetrates the second particle blocker in the first direction, and
wherein the fluid sprayer sprays a fluid toward the second slit.

8. The substrate processing apparatus of claim 1, wherein the laser includes:
a laser generator;
a focusing lens or a minor that reflects the laser beam generated from the laser generator toward the chuck;
a polarizing beam splitter disposed between the laser generator and the focusing lens or the mirror; and
an optical sensor that detects a light beam reflected from the polarizing beam splitter.

9. A substrate processing apparatus, comprising:
a chuck; and
a laser that directs a laser beam toward a substrate disposed on the chuck,
wherein the laser includes:
a laser generator;
a focusing lens or a minor that reflects the laser beam generated from the laser generator toward the substrate on the chuck;
a polarizing beam splitter disposed between the laser generator and the focusing lens or the mirror; and
an optical sensor that detects a light beam reflected from the polarizing beam splitter.

10. The substrate processing apparatus of claim 9, further comprising:
an upper particle blocker disposed on the chuck,
wherein the upper particle blocker includes a second particle blocker,
wherein the second particle blocker includes a second slit that vertically penetrates the second particle blocker.

11. The substrate processing apparatus of claim 10, wherein the upper particle blocker further includes a fluid sprayer disposed on the second particle blocker,
wherein the fluid sprayer sprays a fluid toward the second slit.

12. The substrate processing apparatus of claim 9, further comprising a lower particle blocker disposed between the chuck and the laser,
wherein the lower particle blocker includes a first particle blocker,
wherein the first particle blocker includes a first slit that vertically penetrates the first particle blocker, and
wherein the first slit extends in a horizontal direction.

13. The substrate processing apparatus of claim 12, wherein:
the lower particle blocker further includes a rotational driver that rotates the first particle blocker about an axis that extends in a direction in which the chuck and the laser are spaced apart from each other, and
wherein the lower particle blocker includes two first slits.

14. The substrate processing apparatus of claim 12, wherein the first particle blocker includes metal and/or rubber.

15. The substrate processing apparatus of claim 12, wherein a length of the first slit ranges from about 0.5 cm to about 1.5 cm.

16. The substrate processing apparatus of claim 13, wherein the rotational driver is spaced apart from the first particle blocker.

17. The substrate processing apparatus of claim 12, wherein the first particle blocker further comprises:
a first plate; and
a protrusion that protrudes from a top surface of the first plate in a direction in which the chuck and the laser are spaced apart from each other.

18. The substrate processing apparatus of claim 17, wherein the protrusion includes a material different from a material of the first plate, and
wherein the first slit penetrates the first particle blocker in a first direction and connects a bottom surface of the first plate to a top surface of the protrusion.

19. The substrate processing apparatus of claim 17, wherein a width of the first slit decreases along a direction in which the chuck and the laser are spaced apart from each other.

20. The substrate processing apparatus of claim 19, wherein a cross-section of the first slit has a shape of an isosceles trapezoid.
